(19) United States
(12) Patent Application Publication
(10) Pub. No.: US 2026/0136950 A1
(43) Pub. Date: May 14, 2026

(54) TERMINAL STRUCTURE WITH DEPRESSION REGION BELOW DIELECTRIC WALL AND SEMICONDUCTOR PACKAGE HAVING THE SAME

(71) Applicant: BRIDGE SEMICONDUCTOR CORP., Taipei City (TW)

(72) Inventors: Charles W. C. LIN, Taipei City (TW); Chia-Chung WANG, Hsinchu County (TW)

(21) Appl. No.: 18/947,792

(22) Filed: Nov. 14, 2024

(51) Int. Cl. H01L 23/495; H01L 21/48

(52) U.S. Cl. CPC H10W 70/435; H10W 70/438; H10W 70/458; H10W 70/048

(57) ABSTRACT

A terminal structure of an interconnect substrate is configured with a depression region and includes an electrically conductive element, a crack-inhibiting dielectric wall and an interfacial dielectric layer. The crack-inhibiting dielectric wall, superimposed over the depression region, is a part of a crack-inhibiting dielectric frame which can reduce warpage caused by the application of the interfacial dielectric layer. The depression region has an open lateral end at a periphery of the terminal structure, a closed lateral end opposite to the open lateral end and formed by an outward lateral surface of the electrically conductive element, and a depression surface at a level between top and bottom surfaces of the electrically conductive element. Accordingly, the depression region of the terminal structure can enhance the inspectability of solder joints by promoting the formation of solder fillets.

### FIELD OF THE INVENTION

The present invention relates to a terminal structure and, more particularly, to a terminal structure with a depression region below a dielectric wall and a semiconductor package having the same.

### DESCRIPTION OF RELATED ART

High-performance microprocessors and ASICs require substrates that offer high performance and reliability for signal interconnection. However, in conventional resin laminate substrates, the electroplated copper layer is prone to peeling under stringent operational conditions, making these substrates unreliable for practical use. In specific applications, ceramic materials like alumina or aluminum nitride are preferred for their desirable attributes, including excellent electrical insulation, robust mechanical strength, low coefficient of thermal expansion (CTE), and efficient thermal conductivity. Consequently, multi-layer ceramic substrates, such as HTCC (high temperature co-fired ceramic) or LTCC (low temperature co-fired ceramic), have been developed to meet specific application demands.

In addition to the resin laminate substrates and the multi-layer ceramic substrates mentioned above, copper lead frame substrates have emerged as another favored option. They offer distinct advantages such as high thermal conductivity, excellent electrical properties, and straightforward manufacturing processes. However, there remains a critical need for further improvement to address issues such as warpage, cracking, difficulty in forming solder fillets at terminals due to the susceptibility of cut lead surfaces to oxidation after the singulation process, and other related problems. This pursuit of enhancement is pivotal in ensuring the continued advancement and reliability of high-performance semiconductor devices.

### SUMMARYOF THE INVENTION

An objective of the present invention is to provide an innovative interconnect substrate featuring a crack-inhibiting dielectric frame and depression regions along its periphery. During the manufacture of the interconnect substrate, the crack-inhibiting dielectric frame can reduce warpage caused by the subsequent application of an interfacial dielectric layer and enhance the substrate’s reliability. Additionally, the depression regions can enhance the inspectability of solder joints by promoting the formation of solder fillets.

In accordance with the foregoing and other objectives, the present invention provides an interconnect substrate, which includes a plurality of electrically conductive elements, a crack-inhibiting dielectric frame and an interfacial dielectric layer and is characterized by terminal structures each configured with a depression region and defined by a respective one of the electrically conductive elements, a crack-inhibiting dielectric wall from a part of the crack-inhibiting dielectric frame, and the interfacial dielectric layer. The depression region has an open lateral end at a periphery of the terminal structure, a closed lateral end opposite to the open lateral end, and a depression surface at a level between top and bottom surfaces of the electrically conductive element. The electrically conductive element has an outward lateral surface as the closed lateral end of the depression region and adjacent to the depression surface of the depression region. The crack-inhibiting dielectric wall is superimposed over the depression region and has an inner lateral edge facing in the electrically conductive element and coated by the interfacial dielectric layer. The interfacial dielectric layer laterally covers and surrounds the electrically conductive element and has inner lateral surfaces that form, collectively with the outward lateral surface of the electrically conductive element, a boundary of the depression region.

Also, the present invention provides a semiconductor package configured with depression regions at its periphery. In the semiconductor package, a semiconductor device is attached on the above-mentioned interconnect substrate and electrically connected to the electrically conductive elements, and a sealant is used to encapsulate the semiconductor device.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIGS. 1, 2, and 3 are cross-sectional, top and bottom perspective views, respectively, of a lead frame panel in accordance with the first embodiment of the present invention;

FIGS. 4 and 5 are cross-sectional and top perspective views, respectively, of the structure of FIGS. 1 and 2 further provided with dielectric frame panel in accordance with the first embodiment of the present invention;

FIGS. 6, 7, and 8 are cross-sectional, top and bottom perspective views, respectively, of the structure of FIGS. 4 and 5 further provided with an interfacial dielectric layer in accordance with the first embodiment of the present invention;

FIG. 9 is a cross-sectional view of the structure of FIG. 6 formed with depression regions to finish the fabrication of a un-singulated interconnect substrate in accordance with the first embodiment of the present invention;

FIGS. 10 and 11 are top and bottom perspective views, respectively, of a unit portion of the interconnect substrate illustrated in FIG. 9 in accordance with the first embodiment of the present invention;

FIG. 12 is a cross-sectional view of the structure of FIG. 9 further provided with semiconductor devices in accordance with the first embodiment of the present invention;

FIG. 13 is a cross-sectional view of the structure of FIG. 12 further provided with a sealant in accordance with the first embodiment of the present invention;

FIGS. 14 and 15 is are cross-sectional and top perspective views, respectively, of the structure of FIG. 13 diced into singulated units in accordance with the first embodiment of the present invention;

FIGS. 16 and 17 are cross-sectional and bottom perspective views, respectively, of an individual singulated semiconductor package in accordance with the first embodiment of the present invention;

FIG. 18 is an enlarged bottom perspective view of a circled portion in FIG. 16 in accordance with the first embodiment of the present invention;

FIG. 19 is a cross-sectional view of the structure with a dielectric frame panel and an interfacial dielectric layer applied to the lead frame panel 10 of FIG. 1 in accordance with the second embodiment of the present invention;

FIG. 20 is a cross-sectional view of the structure of FIG. 19 formed with depression regions to finish the fabrication of an un-singulated interconnect substrate in accordance with the second embodiment of the present invention;

FIG. 21 is a cross-sectional view of an interconnect substrate in accordance with the third embodiment of the present invention;

FIG. 22 is a cross-sectional view of the structure of FIG. 21 further provided with semiconductor devices and a sealant in accordance with the third embodiment of the present invention;

FIGS. 23 and 24 are cross-sectional and bottom perspective views, respectively, of a semiconductor package singulated from the structure of FIG. 22 in accordance with the third embodiment of the present invention;

FIG. 25 is an enlarged bottom perspective view of a circled portion in FIG. 23 in accordance with the third embodiment of the present invention;

FIG. 26 is a cross-sectional view of an interconnect substrate in accordance with the fourth embodiment of the present invention;

FIG. 27 is a cross-sectional view of the structure of FIG. 26 further provided with semiconductor devices and a sealant in accordance with the fourth embodiment of the present invention; and

FIG. 28 is a cross-sectional view of a semiconductor package singulated from the structure of FIG. 27 in accordance with the fourth embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

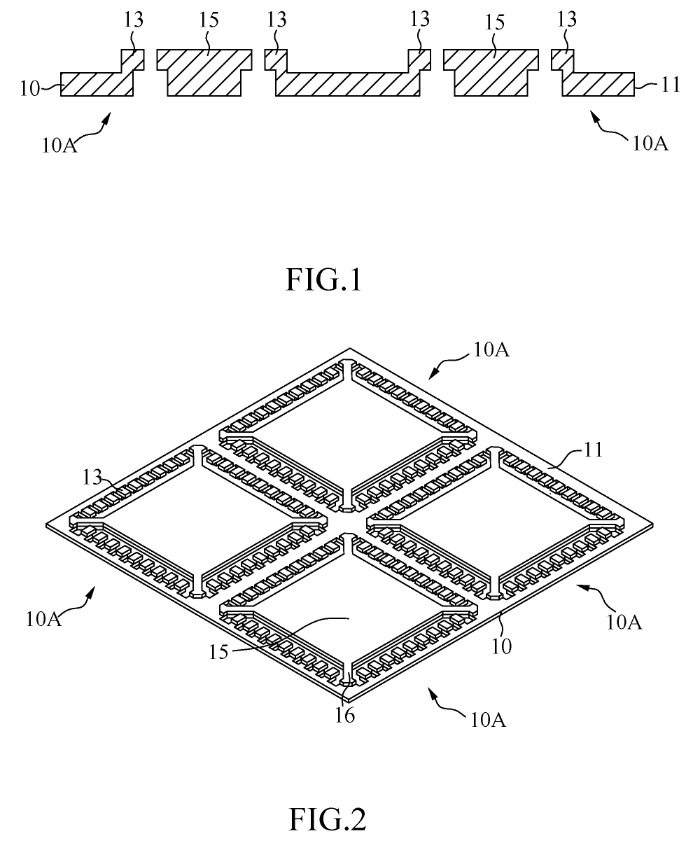

FIGS. 1- 17 are schematic views showing a method of making a semiconductor package that includes an interconnect substrate, a semiconductor device, wires and a sealant in accordance with the first embodiment of the present invention.

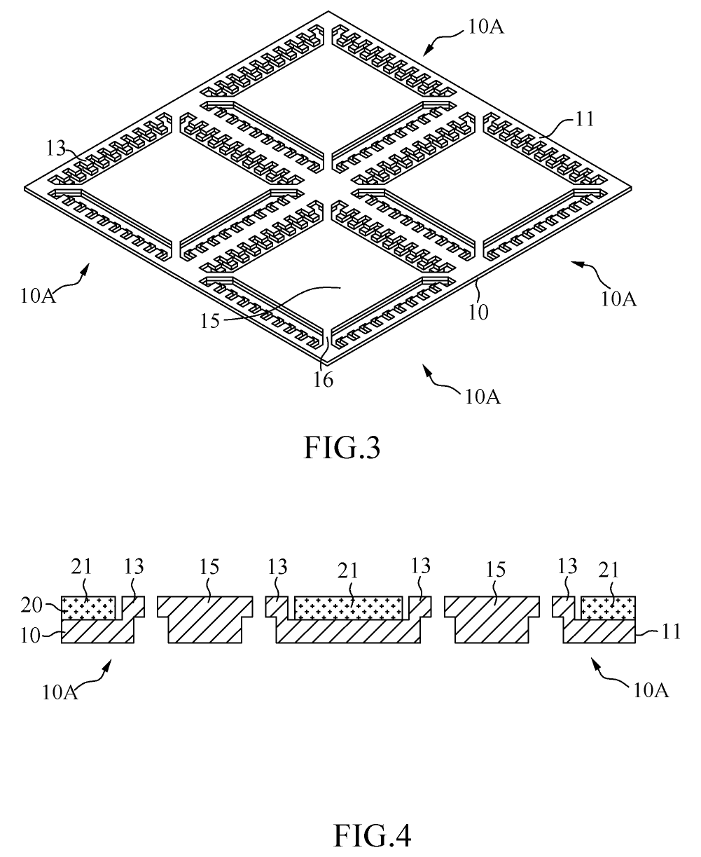

FIGS. 1, 2, and 3, are cross-sectional, top and bottom perspective views, respectively, of a lead frame panel 10. The lead frame panel 10 typically is made of copper, aluminum, alloy 42, iron, nickel, silver, gold, combinations thereof, alloys thereof or any other suitable metals, and can be formed by wet etching or stamping/punching process from a rolled metal strip. The etching process may be a one-sided or two-sided etching to etch through the metal strip and thereby transfers the metal strip into a desired overall pattern of the lead frame panel 10. In this embodiment, the lead frame panel 10 includes a plurality of unit lead frames 10A aligned and connected to one another in an array (such as a 2 x 2 array in this embodiment) form on a plane. Each of the unit lead frames 10A includes a support frame 11, a plurality of electrically conductive elements 13, a thermal pad 15 and a plurality of tie bars 16. The support frames 11 are thinned from above and thus have a thickness less than that of the electrically conductive elements 13 and the thermal pads 15. Each of the electrically conductive elements 13 has a lateral end integrally connected to an inner sidewall of the respective support frame 11. The thermal pad 15 is located at the central area within the respective support frame 11 and connected to the support frame 11 by the tie bars 16. Additionally, in this embodiment, the lead frame panel 10 is further selectively half-etched from its bottom end. Accordingly, the electrically conductive elements 13 have stepped peripheral edges.

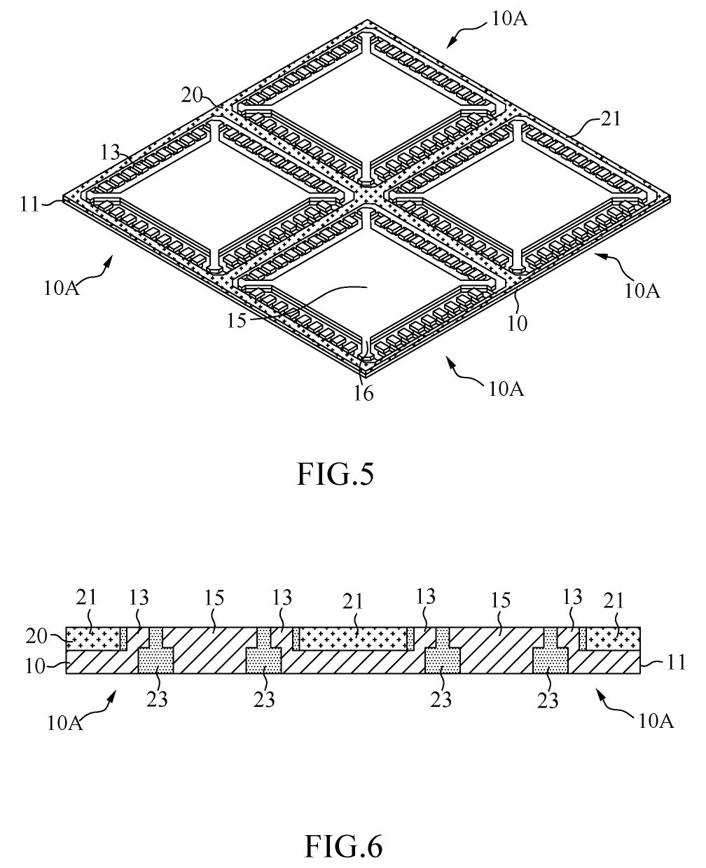

FIGS. 4 and 5, are cross-sectional and top perspective views, respectively, of the structure provided with a dielectric frame panel 20. The dielectric frame panel 20 includes a plurality of crack-inhibiting dielectric frames 21 are aligned and connected to one another in an array (such as a 2 x 2 array in this embodiment) form on the top sides of the support frames 11. The crack-inhibiting dielectric frames 21 may have an elastic modulus lower than 50 Gpa. Preferably, the crack-inhibiting dielectric frames 21 contain reinforcement to enhance the functionality of suppressing crack propagation through the crack-inhibiting dielectric frames 21. For instance, the crack-inhibiting dielectric frame 21 may be made of an organic material (such as epoxy-based material) with glass reinforcement (such as fiberglass). In this illustration, each of the crack-inhibiting dielectric frames 21 has a width greater than that of the support frame 11 and a top surface substantially coplanar with the top surfaces of the electrically conductive elements 13 and the thermal pads 15 as well as the tie bars 16.

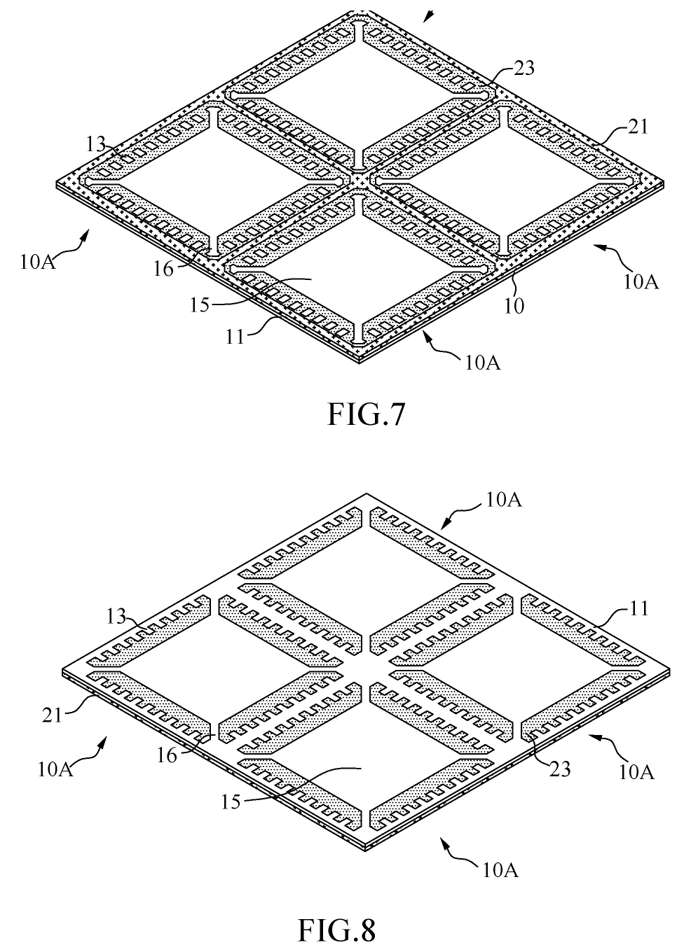

FIGS. 6, 7, and 8 are cross-sectional, top and bottom perspective views, respectively, of the structure provided with an interfacial dielectric layer 23. The interfacial dielectric layer 23 is filled into remaining spaces encircled by the support frames 11 as well as gaps between the electrically conductive elements 13 and the crack-inhibiting dielectric frames 21. As a result, the sidewalls of the electrically conductive elements 13, the thermal pads 15 and the tie bars 16 as well as inner peripheries of the support frames 11 and the crack-inhibiting dielectric frames 21 are covered by the interfacial dielectric layer 23. Due to the crack-inhibiting dielectric frames 21 with an elastic modulus lower than 50 Gpa, the structural warpage caused by the dispensation of the interfacial dielectric layer 23 can be suppressed. In some instances, the interfacial dielectric layer 23 may have an elastic modulus lower than that of the crack-inhibiting dielectric frames 21 to absorb stress and thus further alleviate warpage. Additionally, the interfacial dielectric layer 23 may contain electrically insulative fillers with a coefficient of thermal expansion (CTE) less than 20 ppm dispersed in an organic material (such as epoxy-based material) for alleviating internal expansion and shrinkage of the interfacial dielectric layer 23 during thermal cycling. In this illustration, the top and bottom surfaces of the interfacial dielectric layer 23 are substantially coplanar with the top and bottom surfaces of the electrically conductive elements 13 and the thermal pads 15 as well as the tie bars 16, respectively.

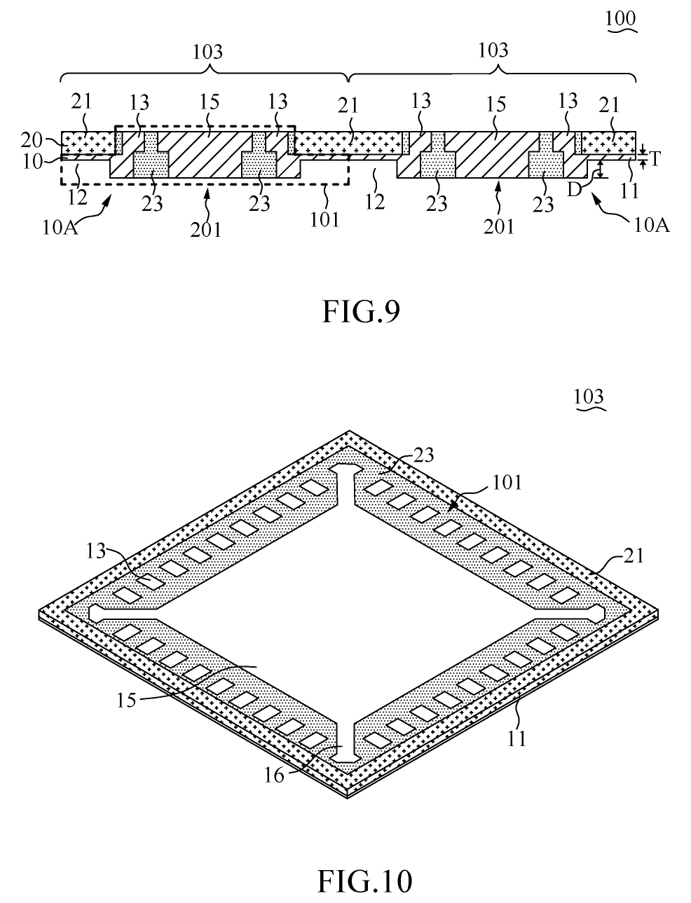

FIG. 9 is a cross-sectional view of the structure formed with depression regions 12 located below the crack-inhibiting dielectric frames 21. Some of the depression regions 12 are adjacent to the outer peripheral edges of the lead frame panel 10, while others are located near interfaces between the neighboring unit lead frames 10A. The depression regions 12 can be formed by, for example, one-sided etching from the bottom side of the lead frame panel 10, and each has an open lateral end at a respective one of the outer peripheral edges of the unit lead frame 10A. In this embodiment, each of the depression regions 12 has a depth D greater than the remaining thickness T of the respective support frame 11 and extends laterally inward beyond the respective inner peripheral edge of the support frame 11.

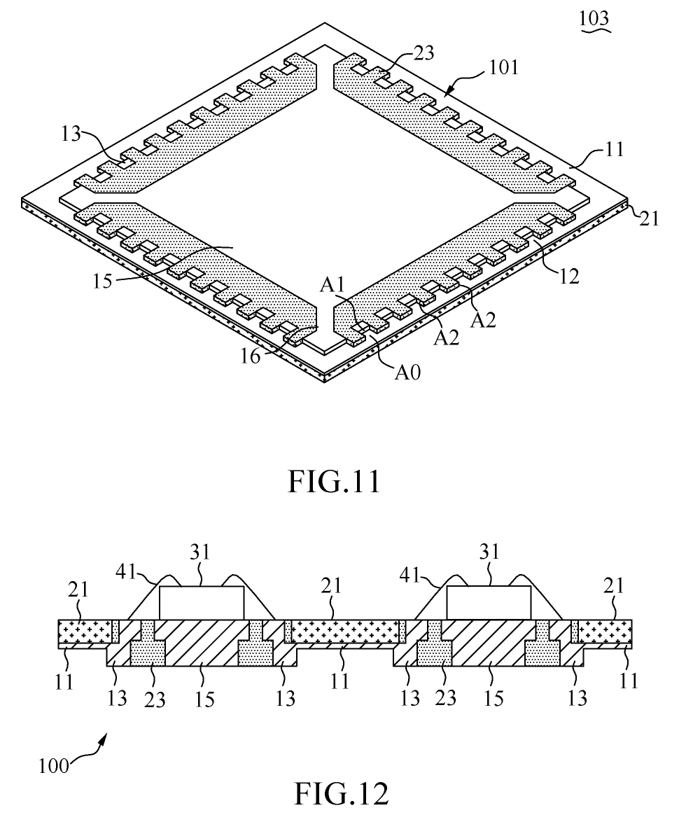

Accordingly, an interconnect substrate 100 in a un-singulated form is accomplished and includes the crack-inhibiting dielectric fames 21 and multiple interconnect units 101. Each of the crack-inhibiting dielectric frames 21 is located all around a respective one of the interconnect units 101. Each of the interconnect units 101, as indicated by the dashed frame, is disposed within a respective one of separate compartments 201 defined by the dielectric frame panel 20 and is configured with the depression regions 12 at the periphery thereof. In this embodiment, the interconnect unit 101 includes the support frame 11, the electrically conductive elements 13, the thermal pad 15, the tie bars 16 (visible in FIGS. 10 and 11) and the interfacial dielectric layer 23.

FIGS. 10 and 11 are top and bottom perspective views, respectively, of a unit portion 103 of the interconnect substrate 100 illustrated in FIG. 9, providing a detailed illustration of terminal structures along the periphery of the interconnect unit 101. Each of the terminal structures has a respective one of the depression regions 12 (visible in FIG. 11), defined by a depression surface A0 and an outward lateral surface A1 of the electrically conductive element 13 and two opposite inner lateral surfaces A2 of the interfacial dielectric layer 23. The outward lateral surface A1 faces the open lateral end of the depression region 12 and is adjacent to and substantially orthogonal to the depression surface A0 and the two opposite inner lateral surfaces A2.

FIG. 12 is a cross-sectional view of the structure provided with semiconductor devices 31 attached to the interconnect substrate 100 illustrated in FIG. 9. Each of the semiconductor devices 31, illustrated as chips, is mounted and superimposed over a respective one of the thermal pads 15 by a thermal adhesive from above and electrically coupled to respective ones of the electrically conductive elements 13 using wires 41.

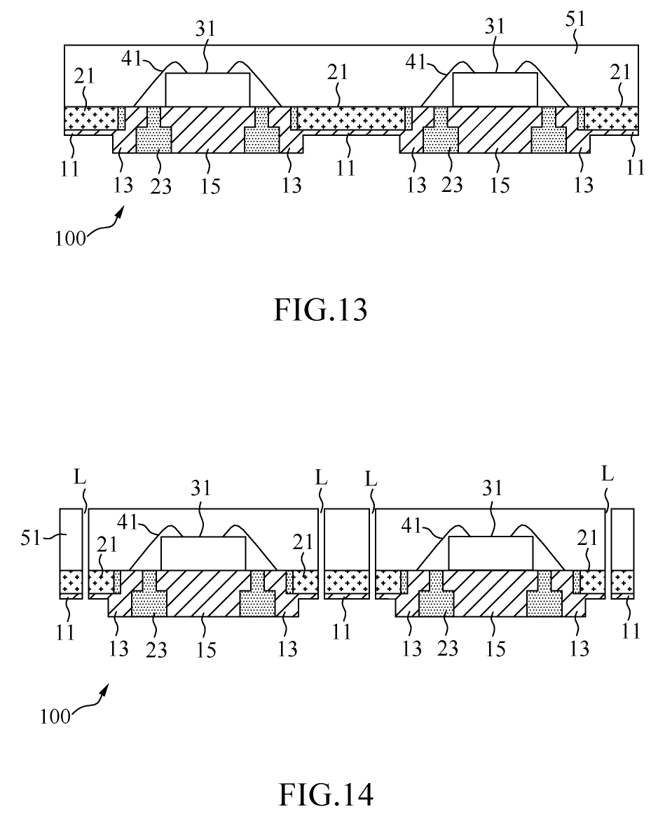

FIG. 13 is a cross-sectional view of the structure optionally provided with a sealant 51. The sealant 51 encapsulates the semiconductor devices 31 and the wires 41 and covers the electrically conductive elements 13, the thermal pads 15, the crack-inhibiting dielectric frames 21 and the interfacial dielectric layer 23 from above, and extends laterally to outer peripheral edges of the interconnect substrate 100.

At this stage, a un-singulated package is accomplished and includes the interconnect substrate 100, the semiconductor devices 31 electrically connected to the interconnect substrate 100 via the wires 41, and the sealant 51 encapsulating the semiconductor devices 31.

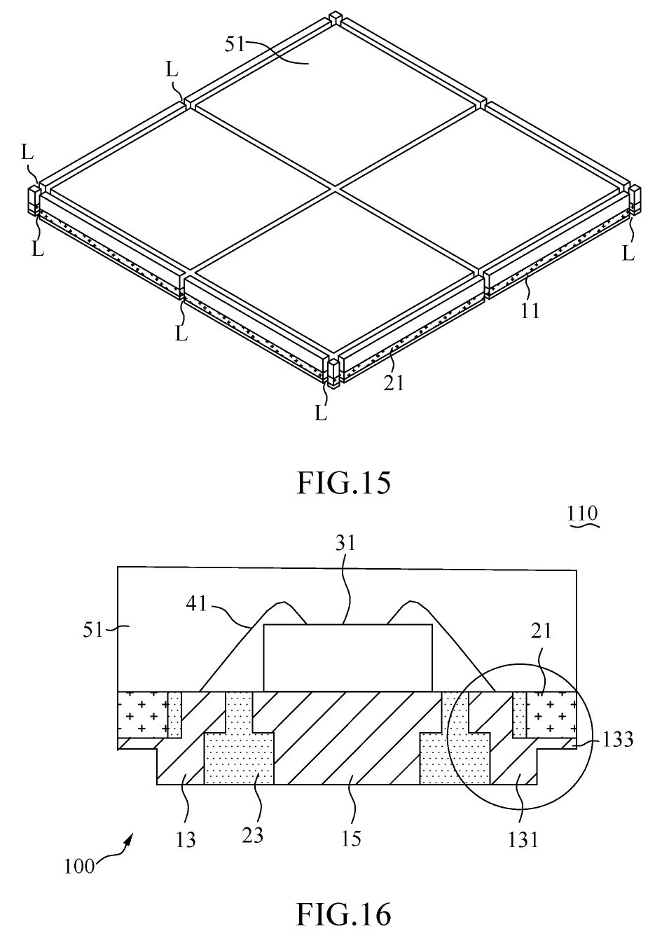

FIGS. 14 and 15 are cross-sectional and top perspective views, respectively, of the structure diced into singulated units. The un-singulated package is divided into individual units along dicing lines “L”, removing portions of the sealant 51 and the crack-inhibiting dielectric frames 21, and all the support frames 11.

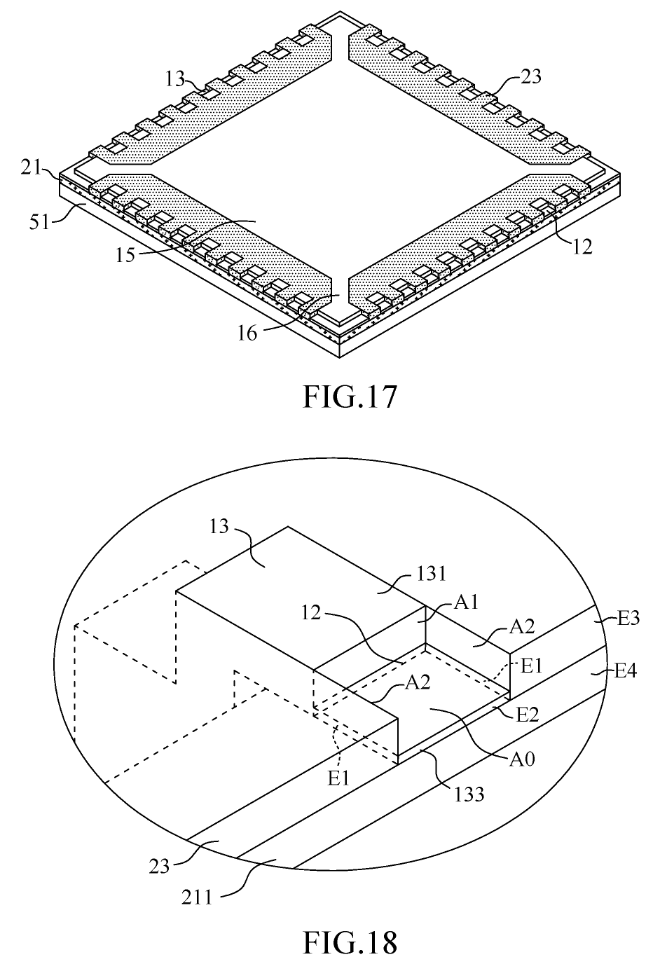

FIGS. 16 and 17 and are cross-sectional and bottom perspective views, respectively, of the individual singulated semiconductor package 110. In this illustration, the semiconductor package 110 includes an interconnect substrate 100 in a singulated form, a semiconductor device 31, wires 41 and a sealant 51. The interconnect substrate 100 in the singulated form includes electrically conductive elements 13, a thermal pad 15, tie bars 16, a crack-inhibiting dielectric frame 21, and an interfacial dielectric layer 23. The electrically conductive elements 13 are spaced from each other and the crack-inhibiting dielectric frame 21 by the interfacial dielectric layer 23. In this embodiment, each of the electrically conductive elements 13 includes a post portion 131 and a flange portion 133. The flange portion 133 extends laterally below the crack-inhibiting dielectric frame 21 from the post portion 131 to the periphery of the interconnect substrate 100, and has a bottom surface at a level between top and bottom surfaces of the post portion 131. The interfacial dielectric layer 23 laterally covers and surrounds sidewalls of the electrically conductive elements 13 and the inner periphery of the crack-inhibiting dielectric frame 21. The semiconductor device 31 is thermally conductible with the thermal pad 15 by a thermal adhesive and electrically connected to the electrically conductive elements 13 via the wires 41. The sealant 51 encapsulates the semiconductor device 31 and extends laterally to an outer periphery of the crack-inhibiting dielectric frame 21.

FIG. 18 is an enlarged bottom perspective views of a circled portion in FIG . 16 for detailed illustration of the terminal structures included in the interconnect substrate 100. The terminal structure is configured with a depression region 12 and mainly includes an electrically conductive element 13, a crack-inhibiting dielectric wall 211 as a part of the aforementioned crack-inhibiting dielectric frame, and an interfacial dielectric layer 23. The crack-inhibiting dielectric wall 211 is superimposed over the depression region 12 and has an outer lateral edge flush with the open lateral end of the depression region 12 and an inner lateral edge facing in the electrically conductive element 13. The post portion 131 of the electrically conductive element 13 has an outward lateral surface A1 as a closed lateral end, opposed to the open lateral end, of the depression region 12. The flange portion 133 of the electrically conductive element 13 extends laterally below the crack-inhibiting dielectric wall 211 from the post portion 131 to the periphery of the terminal structure. More specifically, the flange portion 133 has two opposite lateral edges E1 completely covered by the interfacial dielectric layer 23 and an outer peripheral edge E2 substantially flush with outer lateral edges E3 and E4 of the interfacial dielectric layer 23 and the crack-inhibiting dielectric wall 211. The interfacial dielectric layer 23 laterally covers and surrounds the electrically conductive element 13 and coats the inner lateral edge of the crack-inhibiting dielectric wall 211, and has opposite inner lateral surfaces A2 that form, collectively with the outward lateral surface A1 of the electrically conductive element 13, a boundary of the depression region 12.

### Embodiment 2

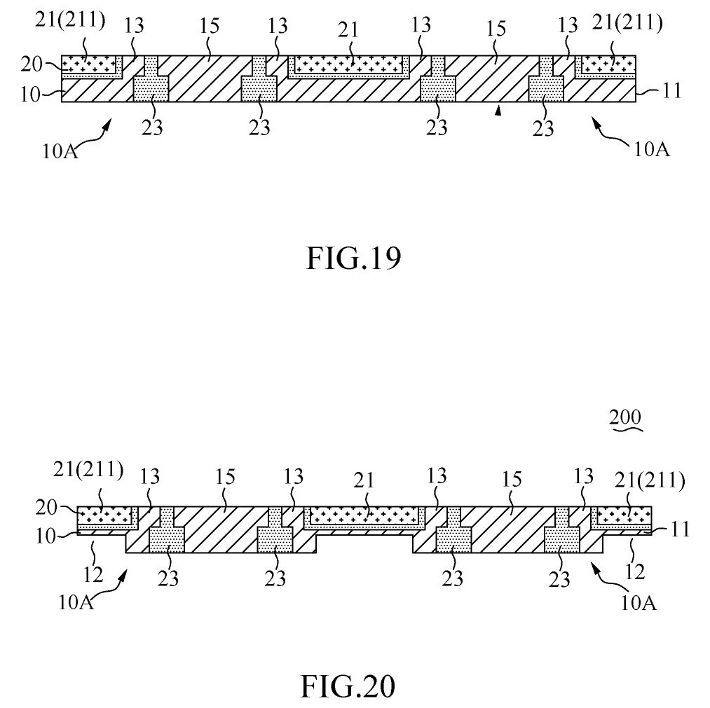

FIGS. 19 and 20 are schematic views showing a method of making an interconnect substrate in accordance with the second embodiment of the present invention. For purposes of brevity, any description in above Embodiment 1 is incorporated herein insofar as the same is applicable, and the same description need not be repeated.

FIG. 19 is a cross-sectional view of the structure with a dielectric frame panel 20 and an interfacial dielectric layer 23 applied to the lead frame panel 10 of FIG. 1. In this embodiment, the dielectric frame panel 20 is attached on the lead frame panel 10 during deposition of the interfacial dielectric layer 23. As a result, the interfacial dielectric layer 23 provides mechanical bond between the bottom sides of the crack-inhibiting dielectric frames 21 and the top sides of the support frames 11.

FIG. 20 is a cross-sectional view of the structure formed with depression regions 12 along peripheral edges of each unit lead frame 10A. By formation of the depression regions 12, the interconnect substrate 200 of this embodiment is accomplished and includes terminal structures similar to that illustrated in FIG. 18 except that the interfacial dielectric layer 23 further extends laterally below the crack-inhibiting dielectric wall 211.

### Embodiment 3

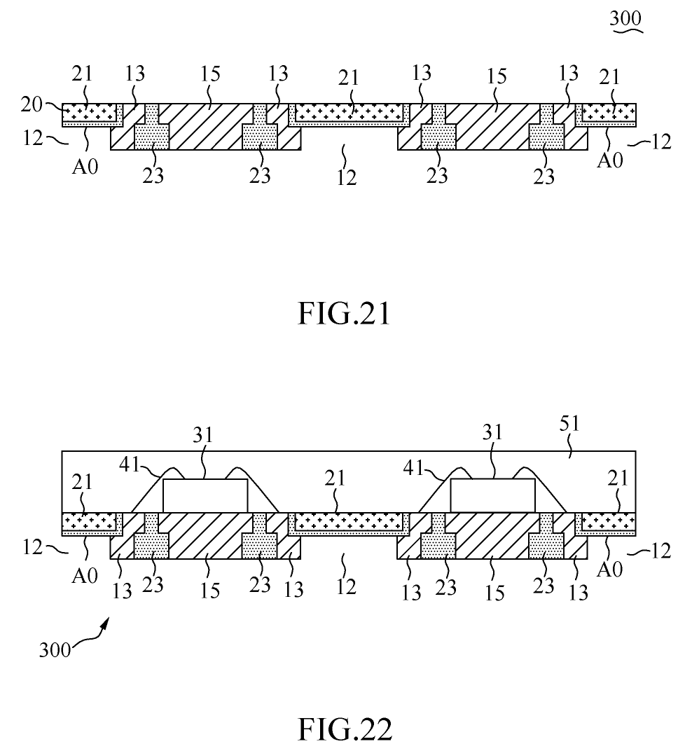

FIGS. 21-23 are schematic views showing a method of making a semiconductor package in accordance with the third embodiment of the present invention. For purposes of brevity, any description in above Embodiments is incorporated herein insofar as the same is applicable, and the same description need not be repeated.

FIG. 21 is a cross-sectional view of an interconnect substrate 300. The interconnect substrate 300 of this embodiment is similar to the interconnect substrate 200 illustrated in FIG. 20, except that the interfacial dielectric layer 23 has selected portions exposed from the respective depression regions 12 and serve as the depression surfaces A0 of the depression regions 12.

FIG. 22 is a cross-sectional view of the structure provided with semiconductor devices 31 wire bonded to the interconnect substrate 300 illustrated in FIG. 21 and optionally with a sealant 51 for encapsulation. The semiconductor devices 31 are electrically connected to the interconnect substrate 300 via wires 41 and encapsulated by the sealant 51.

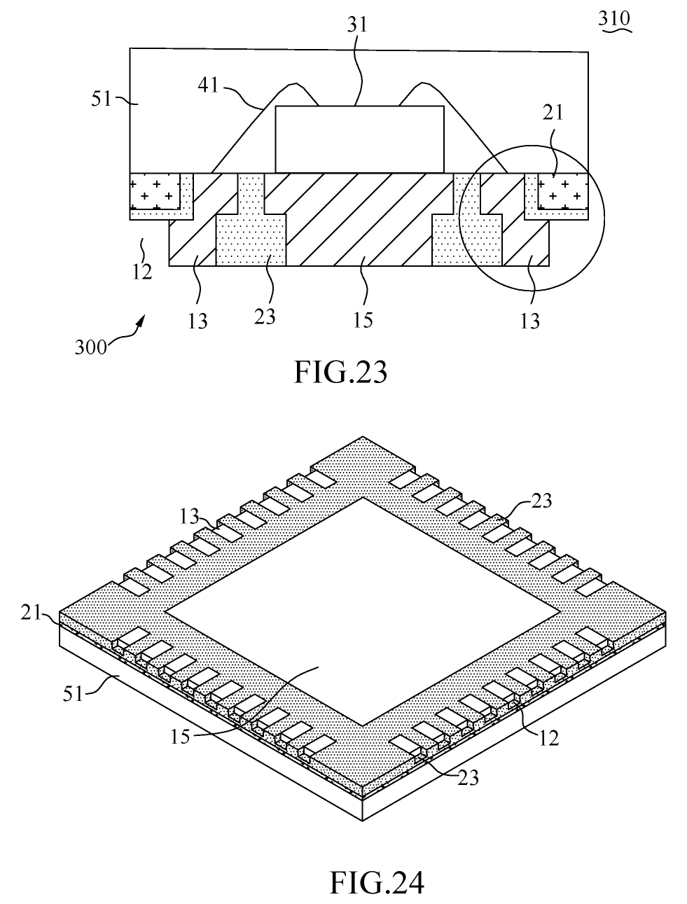

FIGS. 23 and 24 are cross-sectional and bottom perspective views, respectively, of a semiconductor package 310 singulated from the un-singulated package of FIG. 22. The semiconductor package 310 includes electrically conductive elements 13, a thermal pad 15, tie bars 16, a crack-inhibiting dielectric frame 21, an interfacial dielectric layer 23, a semiconductor device 31, wires 41 and a sealant 51.

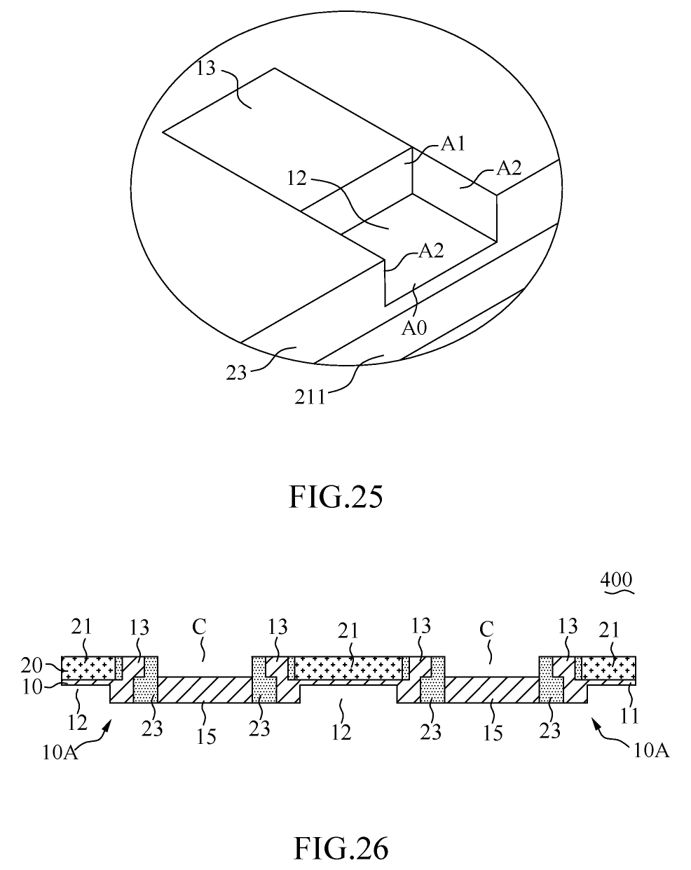

FIG. 25 is an enlarged bottom perspective views of a circled portion in FIG . 23 for detailed illustration of the terminal structure included in the interconnect substrate 300. The terminal structure includes an electrically conductive element 13, a crack-inhibiting dielectric wall 211, and an interfacial dielectric layer 23. A depression region 12 is defined by a depression surface A0 (which is a part of the interfacial dielectric layer 23 in this embodiment), an outward lateral surface A1 of the electrically conductive element 13 and two opposite inner lateral surfaces A2 of the interfacial dielectric layer 23.

### Embodiment 4

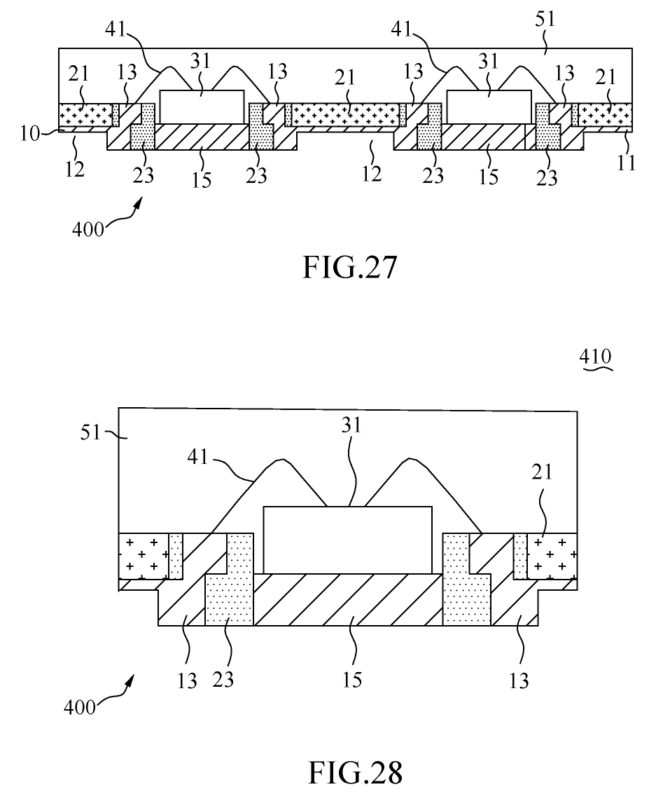

FIGS. 26 and 27 are schematic views showing a method of making a un-singulated package in accordance with the fourth embodiment of the present invention. For purposes of brevity, any description in above Embodiments is incorporated herein insofar as the same is applicable, and the same description need not be repeated.

FIG. 26 is a cross-sectional view of an interconnect substrate 400 in accordance with the fourth embodiment of the present invention. The interconnect substrate 400 is similar to that illustrated in FIG. 9, except that the thermal pads 15 are partially removed by, for example, etching from above to form cavities C for device placement. As a result, the interfacial dielectric layer 23 has inner surrounding sidewalls exposed from the cavities C.

FIG. 27 is a cross-sectional view of the structure provided with semiconductor devices 31 coupled to the interconnect substrate 400 illustrated in FIG. 26 and optionally with a sealant 51 for encapsulation. Each of the semiconductor devices 31 is disposed in the respective cavity C and mounted on the thermal pad 15 by a thermal adhesive and electrically connected to the electrically conductive elements 13 via wires 41. The sealant 51 covers the interconnect substrate 400 and the semiconductor devices 31 as well as the wires 41 from above and extends into remaining spaces in the cavities C.

FIG. 28 is a cross-sectional view of a semiconductor package 410 singulated from the un-singulated package of FIG. 27. The semiconductor package 410 includes a crack-inhibiting dielectric frame 21, electrically conductive elements 13, a thermal pad 15, tie bars (not visible in this figure), an interfacial dielectric layer 23, a semiconductor device 31, wires 41 and a sealant 51.

The terminal structures, interconnect substrates and semiconductor packages described above are merely exemplary. Numerous other embodiments are contemplated. In addition, the embodiments described above can be mixed-and-matched with one another and with other embodiments depending on design and reliability considerations. The semiconductor device can share or not share the thermal pad with other semiconductor devices. For instance, a thermal pad can accommodate a single semiconductor device, and the interconnect substrate can include multiple thermal pads arranged in an array for multiple devices. Alternatively, numerous semiconductor devices can be mounted over a single thermal pad.

As illustrated in the aforementioned embodiments, a distinctive interconnect substrate is configured to exhibit improved reliability and features depression regions at its terminal structures. In the manufacture of the interconnect substrate, a lead frame panel, including a plurality of unit lead frames, is combined with a dielectric frame panel and filled with an interfacial dielectric layer, followed by formation of the depression regions along the peripheries of the unit lead frames. Each of the unit lead frames mainly includes a support frame, electrically conductive elements, optionally a thermal pad and optionally tie bars. The dielectric frame panel includes a plurality of crack-inhibiting dielectric frames, each of which is aligned with and superimposed over the respective support frame. As a result, the un-singulated interconnect substrate includes a plurality of crack-inhibiting dielectric frames and a plurality of interconnect units each disposed within a respective one of separate compartments defined by the crack-inhibiting dielectric frames. In one or more preferred embodiments for the un-singulated interconnect substrate, each of the interconnect units is configured with depression regions along a periphery thereof and mainly includes a support frame, a plurality of electrically conductive elements, an interfacial dielectric layer, optionally a thermal pad and optionally tie bars. Further, by removal of the support frames, an interconnect substrate in a singulated form is obtained, featuring terminal structures along its periphery. Each of the terminal structures is configured with a depression region and includes an electrically conductive element, a crack-inhibiting dielectric wall and an interfacial dielectric layer. The present invention also provides a semiconductor package, in which a semiconductor device is electrically coupled to the above-mentioned interconnect substrate and encapsulated by a sealant.

The depression region typically has an open lateral end at the periphery of the interconnect substrate, a closed lateral end opposite to the open lateral end, and a depression surface at a level between top and bottom surfaces of the electrically conductive element. Further, the depression surface and the closed lateral end of the depression region can be conformally covered by a solderable layer, creating a wettable depression region at the periphery of the interconnect substrate. This promotes the formation of a solder fillet and enhances the inspectability of the solder joint.

The crack-inhibiting dielectric frame typically has inner lateral edges laterally surrounding its respective compartment and outer lateral edges flush with the open lateral ends of the depression regions. In one or more preferred embodiments, the crack-inhibiting dielectric frame has an elastic modulus lower than 50 Gpa and can reduce warpage caused by the subsequent application of the interfacial dielectric layer. Preferably, the crack-inhibiting dielectric frame is made from a filler-free organic material to prevent filler particles from contributing to the frame's susceptibility to cracking. More preferably, the crack-inhibiting dielectric frame is made of an organic material containing reinforcement configured to suppress crack propagation. The top side of crack-inhibiting dielectric frame may be substantially coplanar with top surfaces of the electrically conductive elements, while the bottom side of crack-inhibiting dielectric frame typically is located at a level between the top and bottom surfaces of the electrically conductive elements. In some instances, the bottom side of crack-inhibiting dielectric frame has selected portions as the depression surfaces of the depression regions.

The interfacial dielectric layer covers and contacts and conformally coats sidewalls of the electrically conductive elements and the optional thermal pad as well as the inner lateral edges of the crack-inhibiting dielectric frame. In some instances, the interfacial dielectric layer may further extend laterally below the crack-inhibiting dielectric frame and thus have selected portions as the depression surfaces of the depression regions or between the crack-inhibiting dielectric frame and the depression regions. Typically, the interfacial dielectric layer is made of a different material than the crack-inhibiting dielectric frame. To effectively absorb stress and mitigate warpage of the structure during the application of the interfacial dielectric layer, this layer may possess an elastic modulus lower than that of the crack-inhibiting dielectric frame. In one or more preferred embodiments, the interfacial dielectric layer is composed of an organic material incorporating electrically insulative fillers with low coefficients of thermal expansion (CTE) to alleviate internal expansion and shrinkage of the interfacial dielectric layer during thermal cycling. For instance, the electrically insulative fillers may have CTE less than 20 ppm. The interfacial dielectric layer can have inner lateral surfaces adjacent to the closed lateral end and the depression surface of the respective depression region.

The electrically conductive elements can provide vertical electrical conduction and are spaced from each other by the interfacial dielectric layer. Each of the electrically conductive elements has an outward lateral surface that serves as the closed lateral end of the depression region and is adjacent to and orthogonal or angled to (typically substantially orthogonal to) the depression surface of the depression region and the inner lateral surfaces of the interfacial dielectric layer and extends from the depression surface to the bottom surface of the electrically conductive element. As a result, the inner lateral surfaces of the interfacial dielectric layer and the outward lateral surface of the electrically conductive element collectively form a boundary of the respective depression region. The top and bottom surfaces of the electrically conductive elements can be substantially coplanar with the top and bottom surfaces of the interfacial dielectric layer, respectively. In some instances, the electrically conductive element includes a post portion and a flange portion that extends laterally below the crack-inhibiting dielectric frame from the post portion to the periphery of the interconnect substrate. The flange portion of the electrically conductive element typically has a bottom surface at a level between top and bottom surfaces of the post portion, lateral surfaces completely covered by the interfacial dielectric layer, and an outer edge flush with the open lateral end of the respective depression region and an outer periphery of the interfacial dielectric layer. In a preferred embodiment, the depression region is formed by one-sided etching, and thus the outward lateral surface of the electrically conductive element facing towards the depression region may be an inwardly tapered surface, which slopes inward toward the center of the electrically conductive element as it extends from the depression surface to the bottom surface of the electrically conductive element.

The optional thermal pad can provide thermal conduction with a semiconductor device and is spaced from the electrically conductive elements by the interfacial dielectric layer. The top and bottom surfaces of the thermal pad may be substantially coplanar with the top and bottom surfaces of the electrically conductive elements, respectively. Alternatively, in the example of a cavity being formed and aligned with the thermal pad, the top surface of the thermal pad is lower than the top surface of the electrically conductive element and preferably is located between the top surface and the bottom surface of the interfacial dielectric layer, and the cavity is defined by an inner surrounding sidewall of the interfacial dielectric layer and the top surface of the thermal pad as the bottom of the cavity.

The sealant typically has a higher elastic modulus than that of the interfacial dielectric layer to provide sufficient strength and control the overall flatness of this structure. In a preferred embodiment, the sealant encapsulates the semiconductor device and covers the top surfaces of the electrically conductive elements and the interfacial dielectric layer and extends laterally to the periphery of the semiconductor package.

The semiconductor device may be a packaged or unpackaged chip (e.g. a packaged or unpackaged power chip) and electrically coupled to the electrically conductive elements. In a preferred embodiment, the semiconductor device is superimposed and mounted over the thermal pad using a thermal adhesive and wire bonded to the electrically conductive elements. For the example of a cavity being present at the top side of the thermal pad, the semiconductor device is located within the cavity and laterally surrounded by the inner surrounding sidewall of the interfacial dielectric layer.

The package can be a first-level or second-level single-chip or multi-chip device. For instance, the package can be a first-level package that contains a single chip or multiple chips. Alternatively, the package can be a second-level module that contains a single packaged component or multiple packaged components, and each packaged component can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction and includes contact and non-contact situations. For instance, in a preferred embodiment, the interfacial dielectric layer partially covers sidewalls of the electrically conductive element in a lateral direction, leaving the outward lateral surface of the electrically conductive element uncovered by the interfacial dielectric layer.

The term “surround” refers to relative position between elements regardless of whether the elements are spaced from or adjacent to one another. For instance, in a preferred embodiment, the inner surrounding sidewall of the interfacial dielectric layer laterally surrounds the semiconductor device and is spaced from the semiconductor device by the sealant.

The phrases “mounted on/over” and “attached on/to” include contact and non-contact with a single or multiple element(s). For instance, in a preferred embodiment, the semiconductor device can be attached on the thermal pad and is separated from the thermal pad by the thermal adhesive.

The phrases “electrically connected” and “electrically coupled” refer to direct and indirect electrical connection. For instance, in a preferred embodiment, the semiconductor device is electrically connected to the electrically conductive elements by the bonding wires but does not contact the electrically conductive elements.

The phrase “substantially orthogonal to” refers to deviating not more than 20 degrees from being orthogonal to a plane. In one aspect, substantially orthogonal may mean a relative orientation of from about 70° to about 110°, more preferably from about 80° to about 100°, and most preferably from about 85° to about 95°.

The spatially relative terms, such as “top”, “bottom”, “below”, “above’, “lower”, “upper” and the like, may be used herein for ease of description to describe one element or feature’s relationship to another element(s) or feature(s) as illustrated in the figures. The spatially relative terms are intended to encompass different orientations of the substrate or package in use or operation in addition to the orientation depicted in the figures. For example, if the substrate or package in the figures is turned over, elements described as “below” other elements or features would then be oriented “above” the other elements or features, and “bottom” surfaces would become “top” surfaces. Thus, the example term “below” can encompass both an orientation of above and below. The substrate or package may be otherwise oriented (rotated 90 degrees or at other orientations) and the spatially relative descriptions used herein interpreted accordingly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A terminal structure of an interconnect substrate, the terminal structure being configured with a depression region and comprising an electrically conductive element, a crack-inhibiting dielectric wall and an interfacial dielectric layer, wherein:
the depression region has an open lateral end at a periphery of the terminal structure, a closed lateral end opposite to the open lateral end, and a depression surface at a level between top and bottom surfaces of the electrically conductive element;
the electrically conductive element has an outward lateral surface as the closed lateral end of the depression region and adjacent to the depression surface of the depression region;
the crack-inhibiting dielectric wall is superimposed over the depression region and has an inner lateral edge facing in the electrically conductive element and coated by the interfacial dielectric layer; and
the interfacial dielectric layer laterally covers and surrounds the electrically conductive element and has inner lateral surfaces that form, collectively with the outward lateral surface of the electrically conductive element, a boundary of the depression region.

2. The terminal structure of claim 1, wherein the electrically conductive element includes a post portion and a flange portion that extends laterally below the crack-inhibiting dielectric wall from the post portion towards the periphery of the terminal structure and has a bottom surface at a level between top and bottom surfaces of the post portion.

3. The terminal structure of claim 1, wherein the interfacial dielectric layer further extends laterally below the crack-inhibiting dielectric wall.

4. The terminal structure of claim 3, wherein the interfacial dielectric layer has a selected portion as the depression surface of the depression region.

5. The terminal structure of claim 1, wherein the crack-inhibiting dielectric wall has an elastic modulus lower than 50 Gpa.

6. The terminal structure of claim 1, wherein the crack-inhibiting dielectric wall is an organic material with a reinforcement configured to suppress crack propagation.

7. The terminal structure of claim 1, wherein the interfacial dielectric layer has an elastic modulus lower than that of the crack-inhibiting dielectric wall.

8. The terminal structure of claim 1, wherein the interfacial dielectric layer is an organic material with electrically insulative fillers.

9. The terminal structure of claim 8, wherein the electrically insulative fillers have a coefficient of thermal expansion (CTE) less than 20 ppm.

10. A semiconductor package, comprising:
an interconnect substrate, configured with depression regions along a periphery thereof and including a plurality of electrically conductive elements, a crack-inhibiting dielectric frame and an interfacial dielectric layer;
a semiconductor device, attached to the interconnect substrate and electrically connected to the electrically conductive elements; and
a sealant, encapsulating the semiconductor device, wherein:
each of the depression regions has an open lateral end at the periphery of the interconnect substrate, a closed lateral end opposite to the open lateral end, and a depression surface at a level between top and bottom surfaces of the electrically conductive elements;
the electrically conductive elements are disposed within compartments defined by the crack-inhibiting dielectric frame and spaced from each other by the interfacial dielectric layer and each has an outward lateral surface as the closed lateral end of the depression region and adjacent to the depression surface of the depression region;
the crack-inhibiting dielectric frame is superimposed over the depression regions and has inner lateral edges coated by the interfacial dielectric layer; and
the interfacial dielectric layer laterally covers and surrounds the electrically conductive elements and has inner lateral surfaces that form, collectively with the outward lateral surfaces of the electrically conductive elements, boundaries of the depression regions.

11. The semiconductor package of claim 10, wherein each of the electrically conductive elements includes a post portion and a flange that extends laterally below the crack-inhibiting dielectric frame from the post portion towards the periphery of the interconnect substrate and has a bottom surface at a level between top and bottom surfaces of the post portion.

12. The semiconductor package of claim 10, wherein the interfacial dielectric layer further extends laterally below the crack-inhibiting dielectric frame.

13. The semiconductor package of claim 12, wherein the interfacial dielectric layer has selected portions as the depression surfaces of the depression regions.

14. The semiconductor package of claim 10, wherein the interconnect substrate further includes a thermal pad with sidewalls laterally covered and surrounded by the interfacial dielectric layer, and the semiconductor device is disposed over the thermal pad.

15. The semiconductor package of claim 10, wherein the crack-inhibiting dielectric frame has an elastic modulus lower than 50 Gpa.

16. The semiconductor package of claim 10, wherein the crack-inhibiting dielectric frame is an organic material with a reinforcement configured to suppress crack propagation.

17. The semiconductor package of claim 10, wherein the interfacial dielectric layer has an elastic modulus lower than that of the crack-inhibiting dielectric frame.

18. The semiconductor package of claim 10, wherein the interfacial dielectric layer is an organic material with electrically insulative fillers.

19. The semiconductor package of claim 18, wherein the electrically insulative fillers have a coefficient of thermal expansion (CTE) less than 20 ppm.
